(19) United States
(12) Patent Application Publication
(10) Pub. No.: US 2007/0217471 A1
(43) Pub. Date: Sep. 20, 2007

(54) Laser diode stack utilizing a non-conductive submount

(75) Inventors: Mark Joseph DeFranza, Ridgefield, WA (US); David Clifford Dawson, Brush Prairie, WA (US); Jason Nathaniel Farmer, Vancouver, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 11/492,140

(22) Filed: Jul. 24, 2006

Related U.S. Application Data
(63) Continuation-in-part of application No. 11/384,940, filed on Mar. 20, 2006.
(63) Continuation-in-part of application No. 11/417,581, filed on May 4, 2006.

(51) Int. Cl. H01S 3/04; H01S 5/00

(52) U.S. Cl. 372/50.12; 372/36

(57) ABSTRACT

A laser diode package is provided, the package including a plurality of laser diode submount assemblies. Each laser diode submount assembly includes a submount comprised of a non-conductive material. At least one laser diode is attached to a first portion of one surface of each submount while a spacer is attached to a second portion of the same submount surface. Preferably the submount has a high thermal conductivity and a CTE that is matched to that of the laser diode. The laser diode stack is formed by mechanically coupling the bottom surface of each submount to the spacer of an adjacent submount assembly. The individual laser diodes of the fabricated stack can be serially coupled together, coupled together in parallel, or individually addressable. To provide package cooling, the laser diode stack is thermally coupled to a cooling block.

### CROSS-REFERENCE TO RELATED APPLICATION

This application is a continuation-in-part of U.S. patent application Ser. No. 11/384,940, filed Mar. 20, 2006, and Ser. No. 11/417,581, filed May 4, 2006, the disclosures of which are incorporated herein by reference for any and all purposes.

### FIELD OF THE INVENTION

The present invention relates generally to semiconductor lasers and, more particularly, to a laser diode stack that provides improved performance and versatility.

### BACKGROUND OF THE INVENTION

High power laser diodes have been used individually and in arrays in a wide range of applications including materials processing, medical devices, printing/imaging systems and the defense industry. Furthermore due to their size, efficiency and wavelength range, they are ideally suited as a pump source for high power solid state lasers. Unfortunately reliability issues have prevented their use in a number of critical applications such as space-based systems in which launch costs coupled with the inaccessibility of the systems once deployed requires the use of high reliability components.

During operation, a laser diode produces excessive heat which can lead to significant wavelength shifts, premature degradation and sudden failure if not quickly and efficiently dissipated. These problems are exacerbated in a typical laser diode pump array in which the laser diode packing density reduces the area available for heat extraction. Additionally as most high energy pulse lasers require a quasi-CW (QCW) laser diode pump, the extreme thermal cycling of the laser diode active regions typically leads to an even greater level of thermal-mechanical stress induced damage.

One approach to overcoming some of the afore-mentioned problems is a laser diode package (e.g., a G package) in which an efficient heat extracting substrate (e.g., beryllium oxide, copper, copper tungsten, etc.) includes multiple grooves into which individual laser diode bars are soldered using an indium solder. Although this package has improved heat dissipation capabilities, it still suffers from numerous problems. First, the coefficient of thermal expansion (CTE) of the solder does not provide a good match with that of the substrate, leading to solder delamination during thermal cycling. Solder delamination is problematic due to the high drive currents that the solder must conduct into the laser diode as well as the heat which the solder must efficiently transfer from the laser diode to the heat extracting substrate. Second, it is difficult to test the individual laser diode bars before installing them into the grooved substrate, potentially leading to arrays in which one or more of the laser diode bars is defective (i.e., non-operational or out of spec.). Third, mounting the laser diode bars into the individual grooves of the substrate may lead to further stresses if the laser diode bars exhibit any curvature.

Accordingly what is needed in the art is an alternate laser diode package that overcomes the problems inherent in the laser diode packages of the prior art, thereby providing improved reliability and performance. The present invention provides such a laser diode and submount assembly suitable for such a laser diode package.

### SUMMARY OF THE INVENTION

The present invention provides a laser diode package which includes a stack, either a horizontal stack or a vertical stack, of laser diode submount assemblies. Each laser diode submount assembly includes a submount comprised of a non-conductive material. At least one laser diode is attached to a first portion of one surface of each submount while a spacer is attached to a second portion of the same submount surface. Exemplary laser diodes include single mode single emitter laser diodes, broad area multi-mode single emitter laser diodes, and multiple single emitters fabricated on either a single substrate or on multiple substrates. Preferably the submount has a high thermal conductivity and a CTE that is matched to that of the laser diode. The laser diode stack is formed by mechanically coupling the bottom surface of each submount to the spacer of an adjacent submount assembly. The individual laser diodes of the fabricated stack can be serially coupled together, coupled together in parallel, or individually addressable.

In at least one embodiment of the invention, the top surface of each submount includes a first metallization layer interposed between each laser diode and the first portion of each submount, and a second metallization layer interposed between each spacer and the second portion of each submount. A first laser diode contact can be electrically coupled to the first metallization layer, for example with an electrically conductive solder. A second laser diode contact can be electrically coupled to the second metallization layer, for example with wire or ribbon bonds. Preferably a metallization layer deposited on the bottom surface of each submount is electrically coupled to the first metallization layer with one or more electrically conductive vias within the submount.

Serial laser diode coupling is preferably achieved by using an electrically conductive material for the spacers, electrically coupling the spacer of one assembly to a metallization layer deposited on the bottom surface of the adjacent submount, electrically coupling the metallization layer on the bottom surface of the submount to a first metallization layer on the top surface of the submount using electrically conductive vias, mechanically and electrically coupling the laser diode to the first metallization layer, and electrically coupling the second contact of the laser diode to a second metallization layer interposed between the top surface of the submount and the spacer, wherein the first and second metallization layers on the top surface of each submount are electrically isolated from one another.

To provide package cooling, the laser diode stack is thermally coupled to a cooling block. In at least one embodiment, the cooling block includes a slotted region into which the entire laser diode stack fits. Preferably in this embodiment the cooling block is comprised of a pair of members. In at least one embodiment, the cooling block includes a plurality of slotted regions into which fit the submounts of the laser diode submount assemblies.

A further understanding of the nature and advantages of the present invention may be realized by reference to the remaining portions of the specification and the drawings.

### BRIEF DESCRIPTION OF THE DRAWINGS

FIG. 1 is an end view of a typical laser bar according to the prior art;

FIG. 2 shows an end view of a laser diode stack comprised of multiple single-emitter laser diodes;

FIG. 3 shows an end view of a laser diode stack comprised of multiple multi-emitter laser diodes;

FIG. 4 is a perspective view of laser diode submount assembly in accordance with one embodiment of the invention;

FIG. 5 is a perspective view of the bottom surface of the submount used in the laser diode submount assembly of FIG. 4, this view showing the lower metallization layer;

FIG. 6 is a perspective view of the submount used in the laser diode submount assembly of FIG. 4, this view showing the vias that couple the upper and lower metallization layers;

FIG. 7 is a perspective view of a laser diode submount assembly utilizing a second laser diode/spacer configuration;

FIG. 8 is a perspective view of a laser diode stack comprised of multiple submount assemblies of the configuration shown in FIG. 4;

FIG. 9 is a perspective view of a laser diode stack comprised of multiple submount assemblies of the configuration shown in FIG. 7;

FIG. 10 is a perspective view of the laser diode stack of FIG. 8 attached to a cooling block;

FIG. 11 is a perspective view of the laser diode stack of FIG. 9 attached to a cooling block; and

FIG. 12 is a perspective view of the laser diode stack of FIG. 9 attached to an alternate cooling block.

### DESCRIPTION OF THE SPECIFIC EMBODIMENTS

The present invention provides a laser diode submount assembly which can be combined with other laser diode submount assemblies to form either a vertical or horizontal stack. Each laser diode submount assembly includes at least one laser diode. In a preferred embodiment, each laser diode of each submount assembly operates at the same wavelength. In an alternate embodiment, the laser diode or diodes of each submount assembly operate at a different wavelength. In yet another alternate embodiment, the stack includes groups of laser diodes where each group operates at a preset wavelength. It will be appreciated that there are a variety of possible configurations depending upon the number of desired wavelengths and the number of submount assemblies within a specific laser diode package.

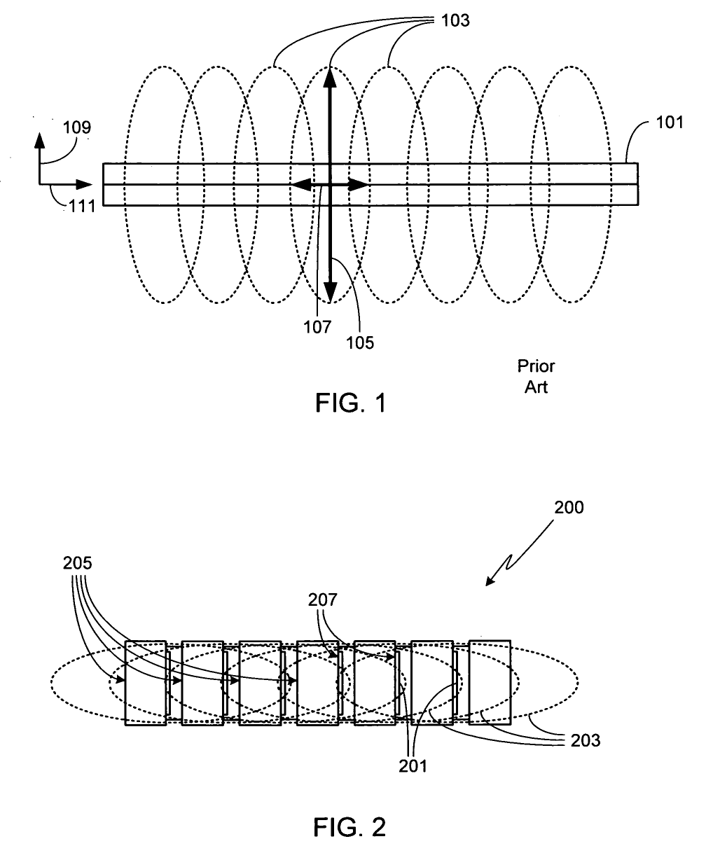

Laser diode bars are used in a variety of high power laser diode applications. FIG. 1 is an end view of a typical laser diode bar 101. As shown, each emitter within the laser bar emits an elliptical beam 103 with the fast axis 105 perpendicular to the diode junction and the slow axis 107 parallel to the diode junction. Thus the combination of the individual output beams from laser bar 101 creates an output that is rapidly diverging along axis 109 and is on the order of 1 centimeter, the length of a laser bar, along axis 111. Note that for illustration clarity, only 8 beams 103 are shown in FIG. 1 although it will be appreciated that a typical laser bar includes many more emitters.

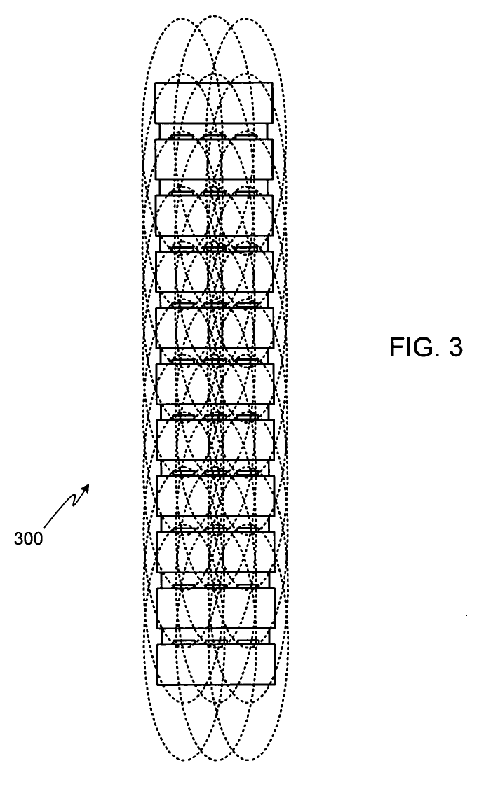

FIGS. 2 and 3 illustrate the difference between the output of a laser bar and a stack of single or multi-emitters. FIG. 2 is an end view of the output from laser diode stack 200 comprised of multiple diode lasers 201, each of which is a single emitter. In marked contrast to the output beam from laser bar 201, the fast axis of the output beams 203 from the laser diode stack subassemblies are co-aligned (i.e., the fast axis of each output beam 203 is substantially orthogonal to the submount mounting surfaces 205 and 207). In addition to providing improved beam geometry for many applications, a laser diode stack as shown provides a simple means of controlling the dimensions of the output beam by varying the number of subassemblies within the stack as well as the number of emitters per subassembly. For example, laser diode stack 300 shown in FIG. 3 includes 10 subassemblies with each subassembly having three emitters on three separate substrates. Additionally, a stack of diode lasers provides improved heat dissipation, the ability to vary the wavelength between subassemblies, and individual laser diode addressability.

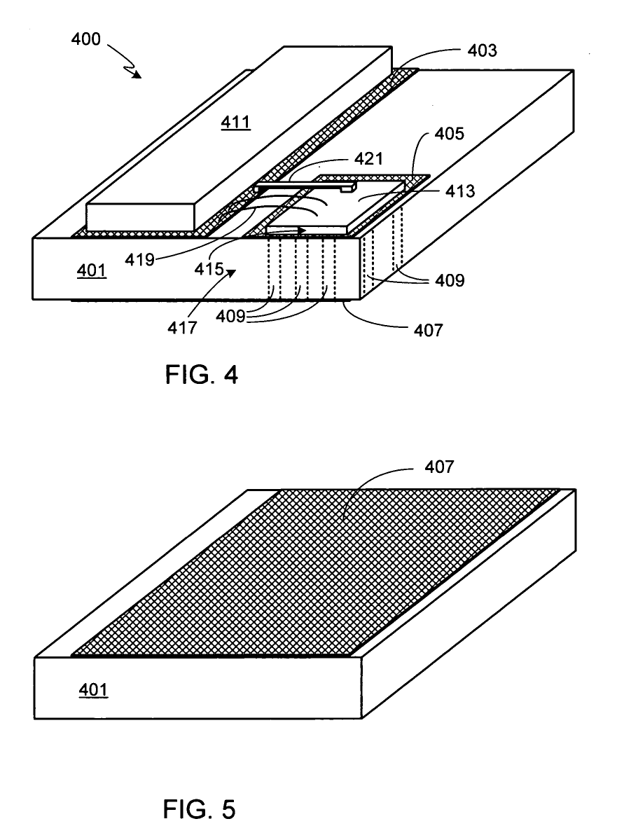

FIGS. 4-6 illustrate a single laser diode submount assembly 400 according to one embodiment of the invention. As shown in the perspective view of FIG. 4, submount assembly 400 is fabricated on a submount 401. To achieve the desired levels of performance and reliability, preferably submount 401 is comprised of a material with a high thermal conductivity and a coefficient of thermal expansion (CTE) that is matched to that of the laser diode. To simplify the design and fabrication of the individual submount assemblies as well as a stack of submount assemblies, submount 401 is comprised of an electrically non-conductive (i.e., electrically isolating) material. A variety of materials (e.g., ceramics) can be used that meet both the thermal and electrical conductivity requirements of the invention. Electrically conductive bonding layers 403 and 405 are deposited on the upper surface of submount 401 while an electrically conductive bonding layer 407 is deposited on the lower surface of submount 401. Metallization layer 407 is also shown in FIG. 5, a perspective view of the bottom surface of submount 401. Preferably metallization layer 405 is comprised of gold-tin, thus overcoming the reliability issues associated with the use of indium solder as a means of bonding the laser diode to the substrate. It will be appreciated that other materials can be used for layer 405 as long as the CTE of the selected material provides a good match with that of the laser diode. Metallization layers 403 and 407 can be fabricated from the same material as layer 405, thus simplifying device fabrication, or fabricated from a different material or materials.

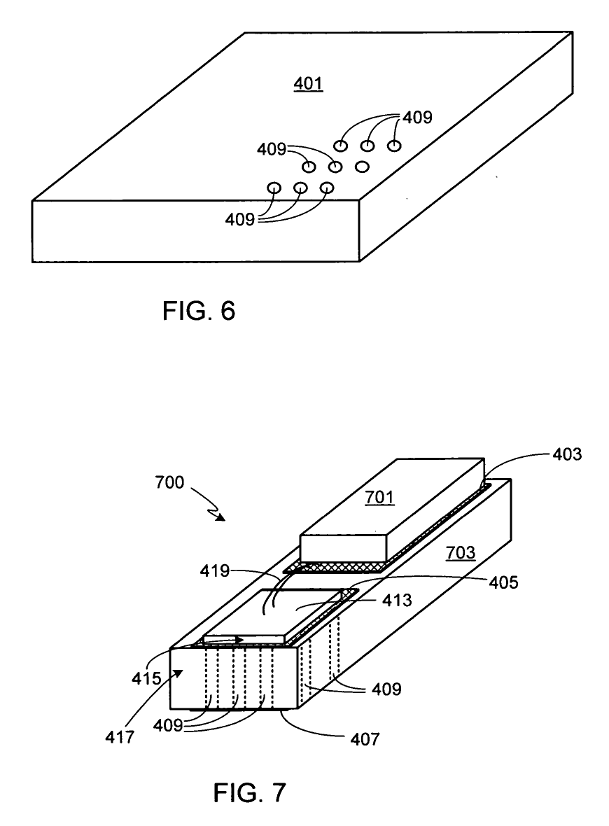

As shown in FIG. 6 (and in phantom in FIG. 4), submount 401 includes at least one via 409, and preferably multiple vias 409, that provide an electrically conductive path between metallization layer 405 and metallization layer 407. Vias 409 can utilize copper or any of a variety of conductive materials.

In the illustrated embodiment, a conductive spacer 411 is mounted on top of, and in electrical contact with, metallization layer 403. Spacer 411 serves as a contact pad, preferably the N contact, for laser 413. Laser 413 is mounted to metallization layer 405, laser 413 positioned such that the emitting facet 415 is substantially parallel with end face 417 of submount 401. Exemplary laser diodes include both single mode single emitter laser diodes and broad area multi-mode single emitter laser diodes. Additionally, multiple single emitters, either fabricated on individual substrates or on a single substrate, can be mounted to submount 401, thereby forming an array of single emitters on a single submount assembly. Laser bars, due both to their size (i.e., 1 centimeter) and their poor heat dissipation characteristics that result from close emitter spacing, are not used with the submount assemblies of the invention.

As previously noted, one contact for laser diode 413, and preferably the N contact, is spacer 411. Laser diode 413 is electrically coupled to conductive spacer 411 using wire bonds, ribbon bonds, or other electrical connector means which couple the laser diode to metallization layer 403. For illustration purposes, both representative wire bonds 419 and a representative contacting member 421 are shown in FIG. 4, although it will be appreciated that in a typical application only a single type of electrical connector would be used. The second contact of laser diode 413, preferably the P contact, is made via metallization layer 407 which, as previously described, is electrically coupled to metallization layer 405 on which laser diode 413 resides. Preferably laser diode 413 is electrically coupled to metallization layer 405 with an electrically conductive solder.

Although FIG. 4 illustrates a side-by-side configuration for contact spacer 411 and laser diode 413, it will be appreciated that the invention is not limited to such a device layout. For example, the contact spacer and the laser diode can be mounted in a front to back configuration. This configuration is shown in FIG. 7 in which contact spacer 701 is mounted behind laser diode 413, thus allowing the width of submount 703 to be substantially equivalent to, or slightly larger than, the widest of either diode 413 or spacer 701. Furthermore and as illustrated, preferably spacer 701 has substantially the same width as laser diode 413. By mounting spacer 701 to the rear of laser diode 413, the separation distances between laser diode 413 and the side surfaces of submount 703 are minimized, thus insuring that the heat from laser diode 413 is efficiently dissipated both laterally, through the sides of submount 703, and vertically, through the bottom of submount 703. Other than for the dimensional variations resulting from this configuration, submount assembly 700 is substantially equivalent to submount assembly 400. For the sake of simplicity, the remaining elements of this configuration which are functionally equivalent to those elements in the configuration of FIG. 4, utilize the same numbering scheme (e.g., metallization layers, vias, wire bonds, etc.). Note that although FIG. 7 only shows wire bonds coupling laser diode 413 to metallization layer 403, as in the previous configuration other contacting means can be used (e.g., contacting member 421).

After completion of the submount assembly regardless of its configuration (e.g., submount assembly 400 or submount assembly 700), preferably the laser diode or diodes 413 attached to each submount are tested. Early testing, i.e., prior to assembly of the entire laser diode package, offers several advantages over testing after package completion. First, it allows defective laser diodes to be identified prior to package assembly, thus minimizing the risk of completing a package assembly only to find that it does not meet specifications due to one or more defective laser diodes. Thus the present package assembly improves on assembly fabrication efficiency, both in terms of time and materials. Second, early testing allows improved matching of the performance of the individual laser diodes within an assembly, for example providing a means of achieving improved wavelength matching between laser diodes or allowing laser diodes operating at different wavelengths to be coupled together in the desired order.

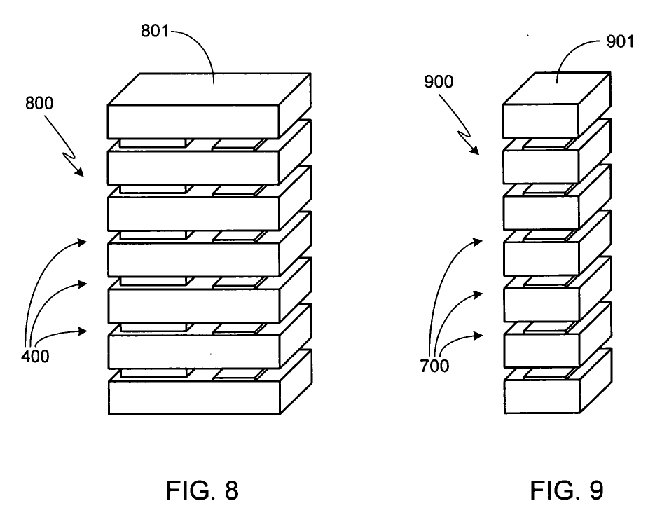

During the next series of steps the laser diode package, which is comprised of a stack of laser diode submount assemblies, is fabricated. The perspective view of FIG. 8 shows a stack 800 comprised of six submount assemblies 400 along with an additional submount 801 while FIG. 9 shows a similar stack 900 comprised of six submount assemblies 700 and an additional submount 901. Although laser diode stacks 800 and 900 can be fabricated without additional submounts 801 and 901, respectively, the inventors have found that it improves the mechanical reliability of the laser diode package. Note that submounts 801 and 901 are preferably comprised of electrically isolating material with upper and lower metallization layers electrically connected together utilizing one or more vias. It will be appreciated that the single emitter stack can utilize fewer, or greater, numbers of submount assemblies and that either horizontal or vertical stack assemblies can be fabricated.

The individual laser diodes of the fabricated stack can be electrically coupled together in a variety of ways. For example, in one preferred embodiment laser diodes 413 are serially coupled together by bonding the upper surface of the contact spacer (e.g., contact 411 of assembly 400 or contact 701 of assembly 700) to a portion of metallization layer 407. Preferably the solder used to couple the contact spacer pads to metallization layer 407 has a lower melting temperature than the solder used to fabricate the individual submount assemblies, thus insuring that during this stage of assembly the reflow process used to combine the submount assemblies will not damage the individual assemblies. In an alternate embodiment of the invention laser diodes 413 are not serially coupled together, rather they are coupled together in parallel, or they are individually addressable. Individual addressability allows a subset of the total number of laser diodes within the stack to be activated at any given time. In order to achieve individual addressability, or to couple the laser diodes together in a parallel fashion, the electrically conductive path between individual submount assemblies must be severed. Severing the conductive path can be accomplished in several ways. For example, spacer 411 (or spacer 701) can be fabricated from a non-conductive material. Alternately, the size of metallization layer 407 can be reduced such that it does not contact spacer 411 (or spacer 701) when a stack of assemblies is formed. The conductive path between assemblies can also be severed by eliminating vias 409 and/or metallization layer 407. Regardless of the technique used to sever the conductive path between assemblies, a variety of techniques can be used to electrically contact each laser diode 413. For example, contact can be made via metallization layers 403 and 405. It will be appreciated that the exact technique used to contact lasers 413 depends on the way in which the conductive path between assemblies is severed.

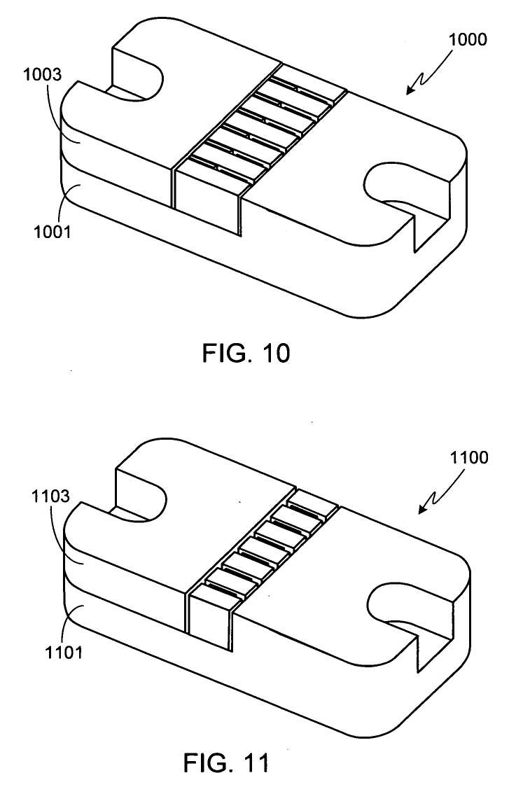

Due to the use of thermally conductive, electrically isolating submounts, a stack of submount assemblies fabricated in accordance with the invention can be directly coupled to a cooling block, even a cooling block fabricated from an electrically conductive material (e.g., copper). A stack of submount assemblies fabricated in accordance with the invention can be integrated into a cooling block in a number of ways, the invention not being limited to a specific cooling block configuration. For example, in one embodiment illustrated in FIGS. 10 and 11, a two piece cooling block is used to capture the laser diode stack. FIG. 10 shows a cooling block 1000 with a laser diode stack such as that illustrated in FIG. 8 while FIG. 11 shows a cooling block 1100 with a laser diode stack such as that illustrated in FIG. 9. Preferably cooling block 1000 is comprised of two parts; a primary member 1001 and a secondary member 1003. Similarly, preferably cooling 1100 is comprised of two parts; a primary member 1101 and a secondary member 1103. The benefit of having two members rather than a single slotted member is that it is easy to achieve a close fit between the cooling block and the laser diode submount stack assembly, thus insuring efficient heat transfer and thus assembly cooling.

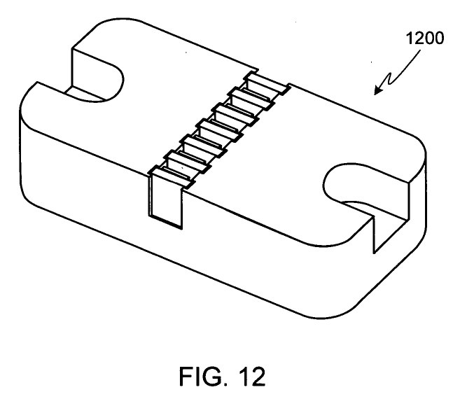

It will be appreciated that a variety of cooling block configurations can be used with the laser diode stacks of the present invention, especially in light of the non-conductive nature of the individual submounts. For example, FIG. 12 is a perspective view of a cooling block 1200, the cooling block including slots into which the edges of the individual submounts fit. Preferably the edges of the individual submounts are bonded to the internal surfaces of the slots with a thermally conductive material. It will be appreciated that a similar configuration can be used with other submount assembly stacks, for example one such as that shown in FIG. 8.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A laser diode package comprising:
a plurality of laser diode submount assemblies, wherein each of said plurality of laser diode submount assemblies comprises:
a submount with a first portion and a second portion, said submount comprised of an electrically non-conductive material;
at least one laser diode attached to said first portion of a first surface of said submount, wherein a fast axis corresponding to an output beam of said at least one laser diode is substantially orthogonal to said first surface of said submount; and
a spacer attached to said second portion of said first surface of said submount; and
means for mechanically coupling each laser diode submount assembly spacer to a second surface of said submount of an adjacent laser diode submount assembly.

2. The laser diode package of claim 1, further comprising a first metallization layer interposed between said at least one laser diode and said first portion of said submount and a second metallization layer interposed between said spacer and said second portion of said submount, wherein said first metallization layer is electrically isolated from said second metallization layer.

3. The laser diode package of claim 2, further comprising a third metallization layer deposited on said second surface of said submount, wherein said submount further comprises at least one electrically conductive via, wherein said at least one electrically conductive via electrically couples said first metallization layer to said third metallization layer.

4. The laser diode package of claim 3, each of said plurality of laser diode submount assemblies further comprising:
means for electrically coupling a first contact of said at least one laser diode to said first metallization layer;
means for electrically coupling a second contact of said at least one laser diode to said second metallization layer;
wherein said spacer is comprised of an electrically conductive material; and
wherein said mechanically coupling means further comprises means for electrically coupling each laser diode submount assembly spacer to said third metallization layer deposited on said second surface of said submount.

5. The laser diode package of claim 4, wherein said means for electrically coupling said first contact of said at least one laser diode to said first metallization layer is comprised of an electrically conductive solder.

6. The laser diode package of claim 4, wherein said means for electrically coupling said second contact of said at least one laser diode to said second metallization layer is comprised of at least one wire bond.

7. The laser diode package of claim 4, wherein said means for electrically coupling said second contact of said at least one laser diode to said second metallization layer is comprised of at least one ribbon bond.

8. The laser diode package of claim 2, each of said plurality of laser diode submount assemblies further comprising:
means for electrically coupling a first contact of said at least one laser diode to said first metallization layer; and
means for electrically coupling a second contact of said at least one laser diode to said second metallization layer.

9. The laser diode package of claim 8, wherein each of said at least one laser diodes is individually addressable.

10. The laser diode package of claim 3, each of said plurality of laser diode submount assemblies further comprising:
means for electrically coupling a first contact of said at least one laser diode to said first metallization layer; and
means for electrically coupling a second contact of said at least one laser diode to said second metallization layer; and
wherein said spacer is comprised of an electrically non-conductive material.

11. The laser diode package of claim 10, wherein each of said at least one laser diodes is individually addressable.

12. The laser diode package of claim 3, each of said plurality of laser diode submount assemblies further comprising:
means for electrically coupling a first contact of said at least one laser diode to said first metallization layer; and
means for electrically coupling a second contact of said at least one laser diode to said second metallization layer; and
wherein said spacer is comprised of an electrically conductive material; and
wherein said spacer is electrically isolated from said third metallization layer on said second surface of said submount.

13. The laser diode package of claim 12, wherein each of said at least one laser diodes is individually addressable.

14. The laser diode package of claim 1, further comprising a cooling block in thermal communication with each submount of said plurality of laser diode submount assemblies.

15. The laser diode package of claim 14, wherein said cooling block is comprised of a first member and a second member, wherein said first and second cooling block members form a slotted region, and wherein said plurality of laser diode submount assemblies fit within said slotted region.

16. The laser diode package of claim 14, wherein said cooling block is comprised of a plurality of slotted regions, wherein each submount of said plurality of laser diode submount assemblies fits within one of said plurality of slotted regions.

17. The laser diode package of claim 1, wherein said first portion of said submount corresponds to a front portion of said first surface of said submount, and wherein said second portion of said submount corresponds to a rear portion of said first surface of said submount.

18. The laser diode package of claim 1, wherein said first and second portions of said first surface of said submount are side-by-side.

19. The laser diode package of claim 1, wherein said at least one laser diode of said plurality of laser diode submount assemblies is a single mode single emitter laser diode.

20. The laser diode package of claim 1, wherein said at least one laser diode of said plurality of laser diode submount assemblies is a broad area multi-mode single emitter laser diode.

21. The laser diode package of claim 1, wherein said at least one laser diode of said plurality of laser diode submount assemblies is comprised of multiple single emitters on multiple substrates.

22. The laser diode package of claim 1, wherein said at least one laser diode of said plurality of laser diode submount assemblies is comprised of multiple single emitters on a single substrate.

23. The laser diode package of claim 1, wherein the fast axis of each laser diode is co-aligned with the fast axis of a corresponding laser diode on said adjacent laser diode submount assembly.
